(19) United States
(12) Patent Application Publication
(10) Pub. No.: US 2017/0330819 A1
(43) Pub. Date: Nov. 16, 2017

(54) HEAT EXCHANGING APPARATUS AND SEMICONDUCTOR REFRIGERATOR HAVING THE SAME

(71) Applicant: QINGDAO HAIER JOINT STOCK CO., LTD., Qingdao City, Shandong Province (CN)

(72) Inventors: HAIBO TAO, Qingdao City, Shandong Province (CN); KUI ZHANG, Qingdao City, Shandong Province (CN); JIANRU LIU, Qingdao City, Shandong Province (CN); PENG LI, Qingdao City, Shandong Province (CN); CHUNYANG LI, Qingdao City, Shandong Province (CN); FEIFEI QI, Qingdao City, Shandong Province (CN); LISHENG JI, Qingdao City, Shandong Province (CN)

(21) Appl. No.: 15/533,649

(22) PCT Filed: Sep. 29, 2015
(86) PCT No.: PCT/CN2015/091093

§ 371 Date: Jun. 6, 2017

(30) Foreign Application Priority Data
Feb. 3, 2015 (CN) 201510056281.7

(51) Int. Cl. H01L 23/427; H01L 23/367; F28D 15/04; H01L 23/473; F28D 15/02

(52) U.S. Cl. CPC H01L 23/427; H01L 23/473; F28D 15/0275; F28D 15/04; H01L 23/3672

(57) ABSTRACT

The present invention is related to a heat exchanging apparatus and a semiconductor refrigerator having the heat exchanging apparatus. Specifically, the present invention provides a heat exchanging apparatus comprising one or more sintered heat pipes. Each sintered heat pipe comprises a main pipe with both ends closed and having a first pipe segment and a second pipe segment, wherein the first pipe segment is configured to connect a heat or cold source, and one or more manifolds for radiating heat or transferring cold extend from one or more portions of the second pipe segment of the main pipe respectively. In addition, the present invention provides a semiconductor refrigerator having the heat exchanging apparatus.

The present application claims the priority of the Chinese patent application No. 201510056281.7 filed on Feb. 3, 2015 and with the title of “Heat Exchanging Apparatus and Refrigerator Having the Same”, which is incorporated herein in its entirety as reference.

### TECHNICAL FIELD

The present invention is related to a heat exchanging apparatus, and more particularly to a heat exchanging apparatus having a sintered heat pipe and a semiconductor refrigerator having the heat exchanging apparatus.

### BACKGROUND

A sintered heat pipe works in the principle that evaporation is utilized to cool a sintered heat pipe so that the temperature difference at the two ends of the heat pipe is quite large to quickly transfer heat. Thanks to their excellent heat transfer performance and other technical advantages, sintered heat pipes are widely used in the field of heat radiation. An existing sintered heat pipe extends from its one end to the other along an exclusive path, which may be linear, L-shaped or U-shaped. One end of the existing sintered heat pipe is an evaporating segment (or a heating segment), and the other end thereof is a condensing segment (or a cooling segment), and a heat insulating segment may be arranged between the evaporating and condensing segments according to the application needs. When one end of the sintered heat pipe is heated, the liquid in the capillary core is evaporated and vaporized. The vapor flows to the other end due to a slight pressure difference, emits heat and condenses into liquid again. Then, the liquid flows to the evaporating segment again under the capillary force along porous materials. This process cycles endlessly, transferring the heat from one end to the other end of the sintered heat pipe. Usually, a heat exchanging apparatus having such a sintered heat pipe is provided with fins on the condensing segment or the evaporating segment of the sintered heat pipe for radiating heat or transferring cold. However, existing heat exchanging apparatuses may not achieve desired effects when radiating heat for heat sources of a high heat flow density such as semiconductor cooling plates.

### SUMMARY

One object of a first aspect of the present invention is to overcome at least one defect of an existing heat exchanging apparatus by providing a novel heat exchanging apparatus.

A further object of the first aspect of the present invention is to improve the heat radiating or cold transferring efficiency of the heat exchanging apparatus so as to adapt to a heat or cold source of a high heat flow density.

One object of a second aspect of the present invention is to provide a semiconductor refrigerator having the heat exchanging apparatus.

The first aspect of the present invention provides a heat exchanging apparatus comprising one or more sintered heat pipes. In particular, each sintered heat pipe comprises a main pipe with both ends closed and having a first pipe segment and a second pipe segment, wherein the first pipe segment is configured to connect a heat or cold source, and one or more manifolds for radiating heat or transferring cold extend from one or more portions of the second pipe segment of the main pipe respectively.

Optionally, the first pipe segment of the main pipe is formed by extending from one end of the main pipe to the other end thereof by a predetermined length, and the second pipe segment of the main pipe is formed by extending from the other end of the main pipe to the one end thereof by a predetermined length.

Optionally, the first pipe segment of the main pipe is a straight pipe, and the first pipe segments of multiple main pipes are located in the same plane in parallel and with gaps therebetween.

Optionally, the heat exchanging apparatus further comprises: a fixed bottom plate whose one surface is provided with one or more grooves, and a fixed cover plate whose one surface is provided with one or more grooves and which is configured to cooperate with the fixed bottom plate to clamp the first pipe segment of the main pipe between the grooves of the fixed cover plate and of the fixed bottom plate.

Optionally, the second pipe segment of the main pipe is a straight pipe, and the second pipe segments of the multiple main pipes are located in the same plane in parallel and with gaps therebetween.

Optionally, the second pipe segment of the main pipe comprises a first straight pipe portion whose one end communicates with the corresponding first pipe segment, and a second straight pipe portion which extends from the other end of the first straight pipe portion perpendicularly relative to the first straight pipe portion and whose tail end is closed, wherein the first straight pipe portions of the second pipe segments of the multiple main pipes are located in the same plane in parallel and with gaps therebetween, and a starting end of a manifold of each sintered heat pipe is located at the first straight pipe portion of the corresponding second pipe segment.

Optionally, the projection of the manifold of each sintered heat pipe in a plane perpendicular to the corresponding first straight pipe portion overlaps with the projection of the corresponding second straight pipe portion in the plane.

Optionally, the manifolds of each sintered heat pipe are located at the same side of the corresponding main pipe, or the manifolds of each sintered heat pipe are located at the opposite sides of the corresponding main pipe respectively.

Optionally, the heat exchanging apparatus further comprises one or two fin groups, each fin group comprising multiple corresponding fins which are arranged in parallel and with gaps therebetween, and each fin group being installed at the manifold on a corresponding side of the main pipe via the pipe holes of the respective fins.

Optionally, the heat exchanging apparatus further comprises a blower arranged at the same side as the multiple manifolds and configured such that an air inlet area of the blower sucks air flow and the air flow is blown to a gap between each two adjacent fins, or the air flow is sucked from the gap between each two adjacent fins and is then blown to the air inlet area.

Optionally, the middle portion of each fin is provided with a receiving through hole so that each fin group defines a receiving space extending along the axes of the receiving through holes; the heat exchanging apparatus further comprises one or two blowers respectively provided in the receiving spaces of the corresponding fin groups and configured such that air flow is sucked from an air inlet area of each blower and is blown to a gap between each two adjacent fins of the corresponding fin group.

The second aspect of the present invention provides a semiconductor refrigerator comprising an inner tank, a semiconductor cooling plate and a heat exchanging apparatus, wherein the heat exchanging apparatus is configured to radiate heat from a hot end of the semiconductor cooling plate to ambient air or to transfer cold from a cold end of the semiconductor cooling plate to a storage compartment of the inner tank. In particular, the heat exchanging apparatus is any of the above heat exchanging apparatuses; the first pipe segment of the main pipe of each sintered heat pipe of the heat exchanging apparatus is connected to the hot or cold end of the semiconductor cooling plate; and the manifold of each sintered heat pipe is configured to radiate heat to ambient air or transfer cold to the storage compartment.

In the heat exchanging apparatus and the semiconductor refrigerator having the heat exchanging apparatus of the present invention, as multiple manifolds for radiating heat or transferring cold extend from the second pipe segment, the heat radiating or cold transferring efficiency of the heat exchanging apparatus and the semiconductor refrigerator is considerably improved, enabling the heat exchanging apparatus to adapt to heat/cold sources of a high heat flow density, such as semiconductor cooling plates, for radiating heat or transferring cold.

Further, thanks to the special structure of each sintered heat pipe in the heat exchanging apparatus and the semiconductor refrigerator having the heat exchanging apparatus of the present invention, the structure of the heat exchanging apparatus is made compact.

The above and other objects, advantages and features of the present invention will be understood by those skilled in the art more clearly with reference to the detailed description of the embodiments of the present below with reference to the accompanied drawings.

### BRIEF DESCRIPTION OF THE DRAWINGS

The followings will describe some embodiments of the present in detail in an exemplary rather than restrictive manner with reference to the accompanying drawings. The same reference signs in the drawings represent the same or similar parts. Those skilled in the art shall understand that these drawings are only schematic ones of this invention, and may not be necessarily drawn according to the scales. In the drawings:

FIG. 1 is a schematic front view of a heat exchanging apparatus according to an embodiment of the present invention;

FIG. 2 is a schematic left view of a heat exchanging apparatus according to an embodiment of the present invention;

FIG. 3 is a schematic front view of a heat exchanging apparatus according to an embodiment of the present invention;

FIG. 4 is a schematic front view of a heat exchanging apparatus according to the another embodiment of the present invention;

FIG. 5 is a schematic front view of a heat exchanging apparatus according to another embodiment of the present invention;

FIG. 6 is a schematic view of a sintered heat pipe of a heat exchanging apparatus according to an embodiment of the present invention;

FIG. 7 is a schematic right view of a semiconductor refrigerator according to an embodiment of the present invention; and

FIG. 8 is a schematic rear view of a semiconductor refrigerator according to an embodiment of the present invention.

Reference signs: 100—inner tank; 150—semiconductor cooling plate; 200—sintered heat pipe; 210—main pipe; 211—first pipe segment; 212—second pipe segment; 213—connecting pipe segment; 220—manifold; 310—fixed bottom plate; 320—fin group; 400—fin group; 410—fin; 500—blower; 2121—first straight pipe portion; 2122—second straight pipe portion.

### DETAILED DESCRIPTION

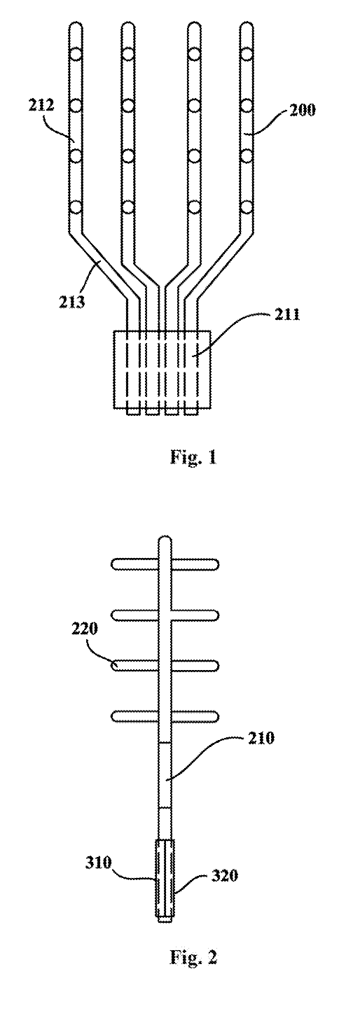

FIG. 1 is a schematic front view of a heat exchanging apparatus according to an embodiment of the present invention. As shown in FIGS. 1-2, an embodiment of the present invention provides a heat exchanging apparatus, which is particularly suitable for radiating heat or transferring cold for a heat or cold source of a high heat flow density such as a semiconductor cooling plate 150, and may be applied in a semiconductor refrigerator. The heat exchanging apparatus may comprise one or more sintered heat pipes 200 to sufficiently utilize the heat conduction performance of the sintered heat pipes 200. In particular, each sintered heat pipe 200 comprises a main pipe 210 with both ends closed and having a first pipe segment 211 and a second pipe segment 212, wherein the first pipe segment 211 is configured to connect the heat or cold source. Preferably, one or more manifolds 220 for radiating heat or transferring cold extend from one or more portions of the second pipe segment 212 of the main pipe 210 respectively to improve the heat radiating or cold transferring efficiency of the heat exchanging apparatus.

In some embodiments of the present invention, the working chamber of the manifold 220 may communicate with the working chamber of the corresponding main pipe 210 to facilitate steam flow in the sintered heat pipe 200. The liquid absorbing core in the manifold 220 may be connected with the liquid absorbing core in the main pipe 210. The liquid absorbing cores in the manifold 220 and in the main pipe 210 closely contact the inner wall of the corresponding pipes respectively to facilitate flow of the working liquid. Further, the diameter of the manifold 220 may equal that of the main pipe 210. In some alternative embodiments of the present invention, the diameter of the manifold 220 may be smaller than that of the main pipe 210.

In some preferred embodiments of the present invention, As shown in FIG. 1, the first pipe segment 211 of the main pipe 210 is formed by extending from one end of the main pipe 210 to the other end thereof by a predetermined length, and the second pipe segment 212 of the main pipe 210 is formed by extending from the other end of the main pipe 210 to the one end thereof by a predetermined length.

For example, the first pipe segment 211 of the main pipe 210 may be a straight pipe, and the first pipe segments 211 of multiple main pipes 210 are located in the same plane in parallel and with gaps therebetween. The second pipe segment 212 of the main pipe 210 may be a straight pipe, and the second pipe segments 212 of multiple main pipes 210 are located in the same plane in parallel and with gaps therebetween. The first and second pipe segments 211, 212 of the main pipe 210 may be arranged to be parallel, and the main pipe 210 may include a connecting pipe segment 213 connected between the first and second pipe segments 211, 212 and arranged at an angle of 100°-170° relative to the first and second pipe segments 211, 212 respectively. The heat exchanging apparatus of the present invention may comprise four sintered heat pipes 200. The main pipes 210 of the four sintered heat pipes 200 are arranged in the same plane in symmetry with respect to a geometrical symmetry plane. The length of the connecting pipe segment 213 of one sintered heat pipe 200 at one side of the geometrical symmetry plane is smaller than that of the connecting pipe segment 213 of the other sintered heat pipe 200 at the same side of the geometrical symmetry plane, so that the four sintered heat pipes 200 are reasonably arranged.

To facilitate heat connection between the sintered heat pipe 200 and the heat source and the cold source and the fixing of the sintered heat pipe 200, the heat exchanging apparatus of the embodiments of the present invention further comprises a fixed bottom plate 310 and a fixed cover plate 320. One surface of the fixed bottom plate 310 is provided with one or more grooves, and the other surface thereof may press the hot end or cold end of the semiconductor cooling plate 150. In other words, the first pipe segment 211 of the sintered heat pipe 200 may be connected to the heat or cold source via the fixed bottom plate 310. One surface of the fixed cover plate 320 is also provided with one or more grooves, and the fixed cover plate 320 is configured to cooperate with the fixed bottom plate 310 to clamp the first pipe segment 211 of the main pipe 210 between the grooves of the fixed cover plate 320 and of the fixed bottom plate 310. After clamping the sintered heat pipe 200 between the fixed cover plate 320 and the fixed bottom plate 310, the three members are firmly fixed together by welding or mechanical squeezing. To effectively transfer heat, usually heat conducting silicone grease is coated on the contact surfaces between the sintered heat pipe 200 and the fixed bottom plate 310/the fixed cover plate 320.

In some embodiments of the present invention, the manifolds 220 of each sintered heat pipe 200 are located at the opposite sides of the corresponding main pipe 210 respectively. There are at least three manifolds 220 at each side of the main pipe 210. The starting ends of the manifolds 220 at each side of the main pipe 210 are arranged with equal gaps respectively along the extending direction of the main pipe 210. The numbers of the manifolds 220 at two sides of the main pipe 210 are the same. Each manifold at one side of the main pipe 220 is one the same line as the corresponding manifold 220 at the other side of the main pipe 210. As well-known by those skilled in the art, the manifolds 220 at one side of the main pipe 210 are arranged with gaps relative to the manifolds 220 at the other side of the main pipe 210. In some preferred embodiments of the present invention, the manifolds 220 of each sintered heat pipe 200 are located at the same side of the corresponding main pipe 210. Each manifold 220 extends outwards from a corresponding part of the corresponding main pipe 210 perpendicularly to a corresponding direction.

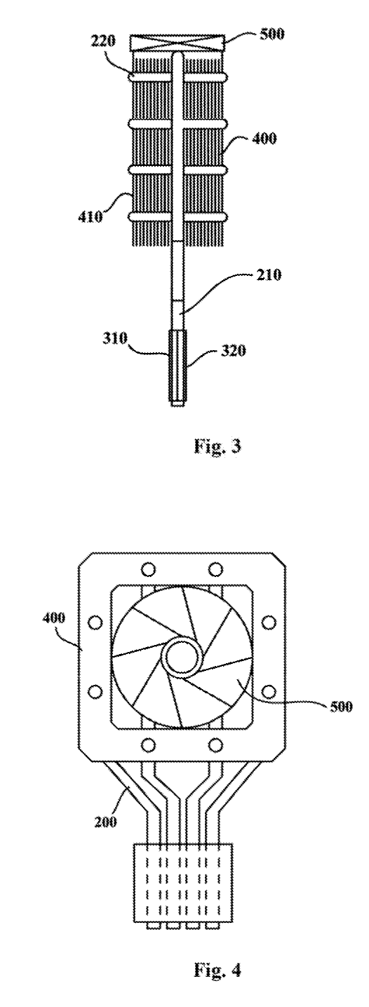

FIG. 3 is a schematic front view of a heat exchanging apparatus according to an embodiment of the present invention. The heat exchanging apparatus in the present embodiment of the present invention may comprise one or more fin groups 400, each fin group 400 comprising multiple corresponding fins 410 which are arranged in parallel and with gaps therebetween, and each fin group being installed at the manifold 220 on a corresponding side of the main pipe 210 via the pipe holes of the respective fins 410 to increase the heat radiating or cold transferring area. The heat exchanging apparatus may further comprise a blower 500 arranged at the same side as the multiple manifolds 220. For example, when the fins 410 are vertically arranged, the blower 500 may be arranged above the fin groups 400. The blower 400 may be configured such that an air inlet area of the blower sucks air flow and the air flow is blown to a gap between each two adjacent fins 410, or the air flow is sucked from the gap between each two adjacent fins 410 and is then blown to the air inlet area. Specifically, the blower 500 may be an axial flow blower 500 fixed on the fin groups 400. The rotary axis of the blades is perpendicular to each manifold 220.

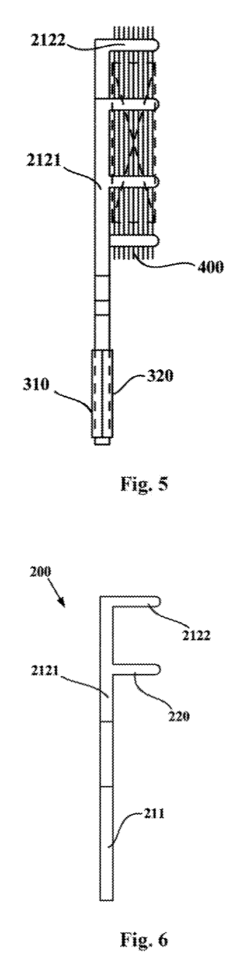

FIG. 4 is a schematic front view of a heat exchanging apparatus according to another embodiment of the present invention. As shown in FIGS. 4-6, the first pipe segment 211 of the main pipe 210 is a straight pipe, and the first pipe segments 211 of multiple main pipes 210 are located in the same plane in parallel and with gaps therebetween. The second pipe segment 212 of the main pipe 210 comprises a first straight pipe portion 2121 whose one end communicates with the corresponding first pipe segment 211, and a second straight pipe portion 2122 which extends from the other end of the first straight pipe portion 2121 perpendicularly relative to the first straight pipe portion 2121 and whose tail end is closed. The first straight pipe portions 2121 of the second pipe segments 212 of multiple main pipes 210 are located in the same plane in parallel and with gaps therebetween. The starting end of a manifold 220 of each sintered heat pipe 200 is located at the first straight pipe portion 2121 of the corresponding second pipe segment 212. The projection of the manifold 220 of each sintered heat pipe 200 in a plane perpendicular to the corresponding first straight pipe portion 2121 overlaps with the projection of the corresponding second straight pipe portion 2122 in the plane.

The heat exchanging apparatus may further comprise multiple fins 410 and multiple blowers 500. The multiple fins 410 are arranged in parallel and with gaps therebetween to form a fin group 400. The middle portion of each fin 410 is provided with a receiving through hole so that each fin group 400 defines a receiving space extending along the axes of the receiving through holes. The multiple blowers are respectively provided in the receiving spaces and configured such that air flow is sucked from an air inlet area of each blower and is blown to a gap between each two adjacent fins 410 of the corresponding fin group 400. The blower 500 is a centrifugal blower. The rotary axis of the blades overlaps with the axis of the receiving through hole, so that air flow is sucked from an axial direction of the centrifugal blower and is blown to the gap between each two adjacent fins 410 using a centrifugal force. The fin 410 is a plate whose middle part is provided with the receiving through hole and whose outer profile is rectangular. The fin group 400 may be installed on the second straight pipe portions 2122 of the main pipe via the pipe holes of the respective fins 410, respectively.

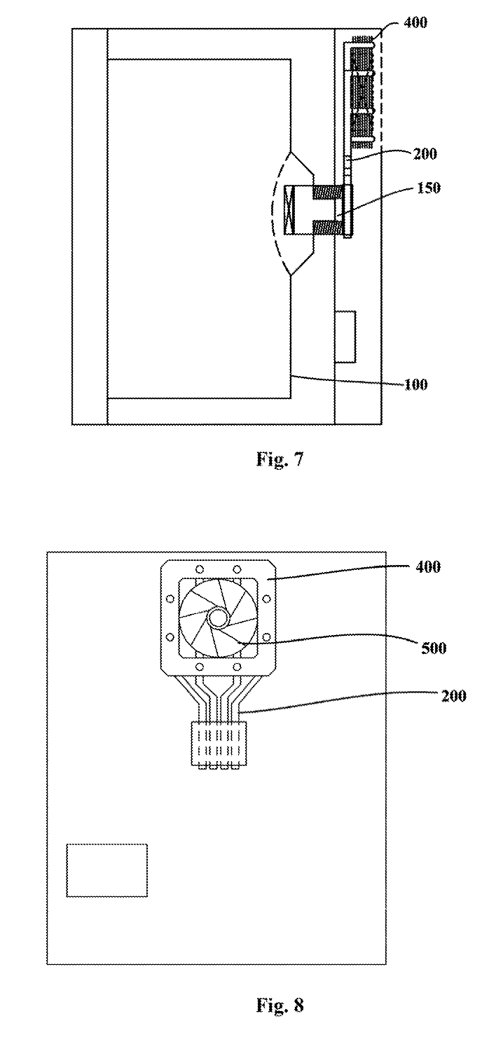

FIG. 7 is a schematic right view of a semiconductor refrigerator according to an embodiment of the present invention. As shown in FIGS. 7-8, the present invention further provides a semiconductor refrigerator, comprising an inner tank 100, a semiconductor cooling plate 150 and a heat exchanging apparatus. The heat exchanging apparatus is configured to radiate heat from a hot end of the semiconductor cooling plate 150 to ambient air or to transfer cold from a cold end of the semiconductor cooling plate 150 to a storage compartment of the inner tank 100. In particular, the heat exchanging apparatus is the heat exchanging apparatus of any of the above embodiments. The first pipe segment 211 of the main pipe 210 of each sintered heat pipe 200 of the heat exchanging apparatus is connected to the hot or cold end of the semiconductor cooling plate 150. The manifold 220 of each sintered heat pipe 200 is configured to radiate heat to ambient air or transfer cold to the storage compartment. When the heat exchanging apparatus is a hot end heat exchanging apparatus, the first pipe segment 211 of the main pipe 210 of each sintered heat pipe 200 of the heat exchanging apparatus is connected to the hot end of the semiconductor cooling plate 150, and the second pipe segment 212 of the main pipe 210 of each sintered heat pipe 200 may be located above the first pipe segment 211. When the heat exchanging apparatus is a cold end heat exchanging apparatus, the first pipe segment 211 of the main pipe 210 of each sintered heat pipe 200 of the heat exchanging apparatus is connected to the cold end of the semiconductor cooling plate 150, and the second pipe segment 212 of the main pipe 210 of each sintered heat pipe 200 may be located below the first pipe segment 211.

Although multiple embodiments of this invention have been illustrated and described in detail, those skilled in the art may make various modifications and variations to the present invention based on the content disclosed by the present invention or the content derived therefrom without departing from the spirit and scope of the present invention. Thus, the scope of the present invention should be understood and deemed to include these and other modifications and variations.

1. A heat exchanging apparatus, comprising one or more sintered heat pipes, and wherein:
each sintered heat pipe comprises a main pipe with both ends closed and having a first pipe segment and a second pipe segment, wherein the first pipe segment is configured to connect a heat or cold source; and
one or more manifolds for radiating heat or transferring cold extend from one or more portions of the second pipe segment of the main pipe respectively.

2. The heat exchanging apparatus of claim 1, wherein:
the first pipe segment of the main pipe is formed by extending from one end of the main pipe to the other end thereof by a predetermined length; and
the second pipe segment of the main pipe is formed by extending from the other end of the main pipe to the one end thereof by a predetermined length.

3. The heat exchanging apparatus of claim 1, wherein the first pipe segment of the main pipe is a straight pipe, and the first pipe segments of multiple main pipes are located in the same plane in parallel and with gaps therebetween.

4. The heat exchanging apparatus of claim 1, further comprising:
a fixed bottom plate whose one surface is provided with one or more grooves; and
a fixed cover plate whose one surface is provided with one or more grooves and which is configured to cooperate with the fixed bottom plate to clamp the first pipe segment of the main pipe between the grooves of the fixed cover plate and of the fixed bottom plate.

5. The heat exchanging apparatus of claim 1, wherein the second pipe segment of the main pipe is a straight pipe, and the second pipe segments of the multiple main pipes are located in the same plane in parallel and with gaps therebetween.

6. The heat exchanging apparatus of claim 1, wherein the second pipe segment of the main pipe comprises a first straight pipe portion whose one end communicates with the corresponding first pipe segment, and a second straight pipe portion which extends from the other end of the first straight pipe portion perpendicularly relative to the first straight pipe portion and whose tail end is closed, wherein the first straight pipe portions of the second pipe segments of the multiple main pipes are located in the same plane in parallel and with gaps therebetween, and a starting end of a manifold of each sintered heat pipe is located at the first straight pipe portion of the corresponding second pipe segment.

7. The heat exchanging apparatus of claim 6, wherein the projection of the manifold of each sintered heat pipe in a plane perpendicular to the corresponding first straight pipe portion overlaps with the projection of the corresponding second straight pipe portion in the plane.

8. The heat exchanging apparatus of claim 1, wherein the manifolds of each sintered heat pipe are located at the same side of the corresponding main pipe, or the manifolds of each sintered heat pipe are located at the opposite sides of the corresponding main pipe respectively.

9. The heat exchanging apparatus of claim 8, further comprising: one or two fin groups, each fin group comprising multiple corresponding fins which are arranged in parallel and with gaps therebetween, and each fin group being installed at the manifold on a corresponding side of the main pipe via the pipe holes of the respective fins.

10. The heat exchanging apparatus of claim 9, further comprising: a blower arranged at the same side as the multiple manifolds and configured such that an air inlet area of the blower sucks air flow and the air flow is blown to a gap between each two adjacent fins, or the air flow is sucked from the gap between each two adjacent fins and is then blown to the air inlet area.

11. The heat exchanging apparatus of claim 9, wherein the middle portion of each fin is provided with a receiving through hole so that each fin group defines a receiving space extending along the axes of the receiving through holes; and
the heat exchanging apparatus further comprises one or two blowers respectively provided in the receiving spaces of the corresponding fin groups and configured such that air flow is sucked from an air inlet area of each blower and is blown to a gap between each two adjacent fins of the corresponding fin group.

12. A semiconductor refrigerator comprising an inner tank, a semiconductor cooling plate and a heat exchanging apparatus, wherein the heat exchanging apparatus is configured to radiate heat from a hot end of the semiconductor cooling plate to ambient air or to transfer cold from a cold end of the semiconductor cooling plate to a storage compartment of the inner tank, wherein the semiconductor refrigerator comprises:
the heat exchanging apparatus is the heat exchanging apparatus according to claim 1;
the first pipe segment of the main pipe of each sintered heat pipe of the heat exchanging apparatus is connected to the hot or cold end of the semiconductor cooling plate; and
the manifold of each sintered heat pipe is configured to radiate heat to ambient air or transfer cold to the storage compartment.
